(19) United States
(12) Patent Application Publication
(10) Pub. No.: US 2025/0342076 A1
(43) Pub. Date: Nov. 6, 2025

(54) MEMORY SYSTEM FOR SETTING FAIL FLAG IN FAIL MEMORY UNIT AND METHOD THEREOF

(71) Applicant: SK hynix Inc., Icheon-si (KR)

(72) Inventors: Hyeong Ju NA, Icheon-si (KR); Min Chul SHIN, Icheon-si (KR)

(21) Appl. No.: 18/938,158

(22) Filed: Nov. 5, 2024

(30) Foreign Application Priority Data
May 2, 2024 (KR) 10-2024-0058446

(51) Int. Cl. G06F 11/07

(52) U.S. Cl. CPC G06F 11/0772; G06F 11/073

(57) ABSTRACT

A memory system may include a memory media and a controller. The memory media may include a plurality of memory chips, each of the plurality of memory chips may include a plurality of memory units, and each of the plurality of memory units may include a plurality of memory cells. The controller may detect a fail memory unit among a plurality of memory units included in the memory media, and may transmit to the memory media a fail flag set command which instructs setting of a fail flag for the fail memory unit.

### CROSS-REFERENCE TO RELATED APPLICATION

The present application claims priority under 35 U.S.C. § 119(a) to Korean Patent Application No. 10-2024-0058446 filed in the Korean Intellectual Property Office on May 2, 2024, which is incorporated herein by reference in its entirety.

### BACKGROUND

### 1. Technical Field

Embodiments of the present disclosure relate to a memory system that sets a fail flag in a fail memory unit and a method of operation.

### 2. Related Art

In a volatile memory (e.g., SRAM or DRAM), stored data is lost when power supply is cut off, and in a nonvolatile memory (e.g., NAND flash, PRAM or MRAM), stored data is maintained even when power supply is cut off.

A fail may occur in an area of a volatile memory in the course of manufacturing or while using the volatile memory. When it is determined that a fail occurring in data stored in a corresponding area is uncorrectable using an existing ECC (error correction code), the volatile memory needs to restore the data stored in the corresponding area using a different algorithm.

### SUMMARY

Various embodiments of the present disclosure are directed to providing a memory system capable of reducing costs required to manage information on a location where a fail has occurred and of restoring a fail uncorrectable by an ECC, and related methods.

In an aspect, a memory system may include: i) a memory media including a plurality of memory chips, each of the plurality of memory chips including a plurality of memory units and each of the plurality of memory units including a plurality of memory cells; and ii) a controller configured to detect a fail memory unit from among the plurality of memory units included in the memory media, and transmit to the memory media a fail flag set command for setting a fail flag for the fail memory unit.

In another aspect, a method for operating a memory system may include: i) detecting a fail memory unit in a memory media including a plurality of memory chips, each of the plurality of memory chips including a plurality of memory units and each of the plurality of memory units including a plurality of memory cells; ii) transmitting to the memory media a fail flag set command for setting a fail flag for the fail memory unit; and iii) setting the fail flag in the memory media in response to the fail flag set command.

According to the embodiments of the present disclosure, it is possible to reduce costs required to manage information on a location where a fail has occurred and quickly restore a fail uncorrectable by an ECC.

### BRIEF DESCRIPTION OF THE DRAWINGS

FIG. 1 is a diagram illustrating a structure of a memory system according to embodiments of the present disclosure.

FIG. 2 is a diagram illustrating an operation of a memory system according to embodiments of the present disclosure.

FIG. 3 is a diagram illustrating an operation in which a memory system determines whether a specific memory unit is a fail memory unit according to embodiments of the present disclosure.

FIG. 4 is a diagram illustrating an operation in which a memory system sets a fail flag in a fail memory unit according to the embodiments of the present disclosure.

FIG. 5 is a diagram illustrating an operation in which a memory system reads an N number of data units from an N number of memory units according to an embodiment of the present disclosure.

FIG. 6 is a diagram illustrating an operation in which a memory system reads a fail memory unit according to the embodiments of the present disclosure.

FIG. 7 is a diagram illustrating an operation in which a memory system restores a data unit according to an embodiment of the present disclosure.

FIG. 8 is a diagram illustrating a method for operating a memory system according to embodiments of the present disclosure.

### DETAILED DESCRIPTION

Hereinafter, embodiments of the present disclosure are described in detail with reference to the accompanying drawings. Throughout the specification, reference to “an embodiment,” “another embodiment” or the like is not necessarily to only one embodiment, and different references to any such phrase are not necessarily limited to the same embodiment(s). The term “embodiments” when used herein does not necessarily refer to all embodiments.

Various embodiments of the present disclosure are described below in more detail with reference to the accompanying drawings. However, the present invention may be embodied in different forms and variations, and should not be construed as being limited to the embodiments set forth herein. Rather, the described embodiments are provided so that this disclosure will be thorough and complete, and will fully convey the present disclosure to those skilled in the art to which this disclosure pertains. Throughout the disclosure, like reference numerals refer to like parts throughout the various figures and embodiments of the present disclosure.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described in detail, the code or instructions for implementing the operations of the method embodiments may transform the computer, processor, controller, or other signal processing device into a special-purpose processor for performing methods herein.

When implemented at least partially in software, the controllers, processors, devices, modules, units, multiplexers, logic, interfaces, decoders, drivers, generators and other signal generating and signal processing features may include, for example, a memory or other storage device for storing code or instructions to be executed, for example, by a computer, processor, microprocessor, controller, or other signal processing device.

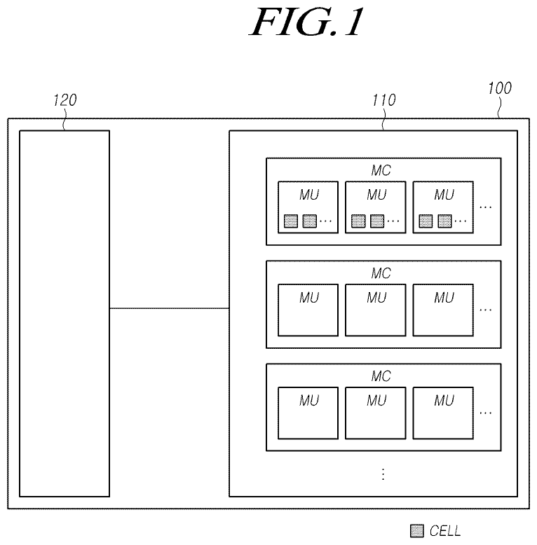

FIG. 1 is a diagram illustrating a structure of a memory system according to embodiments of the present disclosure.

Referring to FIG. 1, a memory system 100 may include a memory media 110 and a controller 120.

The memory media 110 may include a plurality of memory chips MC. Each of the plurality of memory chips MC may include a plurality of memory units MU. Each of the memory units MU may include a plurality of memory cells CELL.

The memory media 110 may control the plurality of memory chips MC in parallel. That is to say, the memory media 110 may execute read operations or write operations on the plurality of memory chips MC in parallel.

The memory media 110 may be implemented in various ways.

For example, the memory media 110 may be configured as a dynamic random access memory media. The memory media 110 may perform a periodic refresh operation to maintain stored data. When power supplied to the memory media 110 is cut off, data stored in the memory media 110 may be lost.

Each of the plurality of memory units MU included in each of the memory chips MC may be a bank, a matrix or a word line.

In another example, the memory media 110 may be implemented with a nonvolatile memory media (e.g., NAND flash or NOR flash). Each of the memory units MU included in the memory media 110 may be a die, a plane or a memory block.

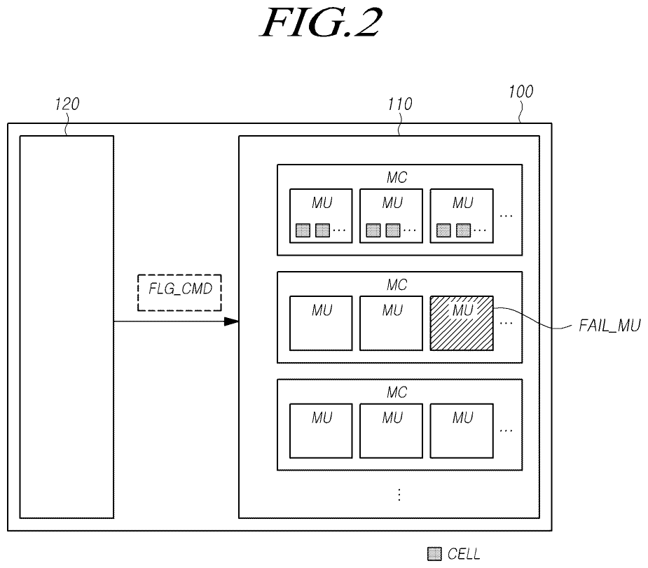

The controller 120 may control the memory media 110. In order to control the memory media 110, the controller 120 may transmit a command to the memory media 110 and receive a response to the command from the memory media 110. This will be described in detail with reference to FIG. 2.

The controller 120 may also be implemented in various ways.

For example, the controller 120 may be implemented with an integrated circuit including logic gates for executing the above-described operations. The controller 120 may be implemented with an application specific integrated circuit (ASIC) or a field programmable gate array (FPGA).

In another example, the controller 120 may include a processor that performs a calculation to control an operation of processing a plurality of operation requests and a working memory that may store data necessary to process the plurality of operation requests.

The processor may control the operation of the controller 120 by executing firmware. The processor may drive the firmware to control overall operations of the controller 120 and to perform logic calculations. The firmware is a program that is executed in the controller 120 to drive the controller 120, and may include binary data in which codes for executing the above-described overall operations and logic calculations are defined.

The firmware may be stored in a storage space (e.g., working memory, ROM, flash) that is located inside or outside of the controller 120. The processor may load all or a part of the firmware stored in the storage space.

The working memory may store data (e.g., a plurality of operation requests or firmware) necessary for the controller 120 to process operation requests. For example, the working memory may include a separate memory media (e.g., SRAM) to store data.

FIG. 2 is a diagram illustrating an operation of a memory system according to embodiments of the present disclosure.

Referring to FIG. 2, a controller 120 of a memory system 100 may detect a fail memory unit FAIL_MU from among a plurality of memory units MU included in a memory media 110.

The fail memory unit FAIL_MU may be a memory unit that may have an uncorrectable error that occurs in the course of reading or writing data.

Specifically, the fail memory unit FAIL_MU may be determined to be a memory unit with lower reliability compared with other memory units. A memory unit MU, from among the plurality of memory units MU, is a fail memory unit FAIL_MU when the controller 120 determines that data stored in the memory unit cannot be restored using an error correction circuit. The controller 120 may classify the memory units MU included in the memory media 110 into fail memory units and normal memory units, which are not fail memory units.

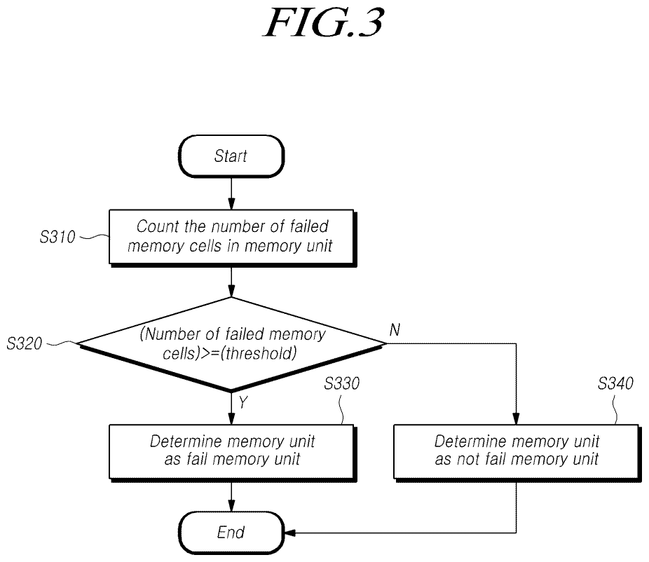

The controller 120 may detect a fail memory unit FAIL_MU using error information that occurs in the course of performing an operation (e.g., a read operation or a write operation) on memory units MU included in the memory media 110. This will be described in detail below with reference to FIG. 3.

The controller 120 may transmit to the memory media 110 a fail flag set command FLG_CMD, which instructs the memory media 110 to set a fail flag for the detected fail memory unit FAIL_MU. The fail flag set command FLG_CMD may include information (e.g., the address or index of the fail memory unit FAIL_MU) to identify the fail memory unit FAIL_MU.

By transmitting the fail flag set command FLG_CMD to the memory media 110, the controller 120 may control the memory media 110 to store information on the location of the fail memory unit FAIL_MU.

As a result, the controller 120 may reduce costs associated with required resources (e.g., SRAM or latch) for directly managing information on the fail memory unit FAIL_MU.

Since the location of the fail memory unit FAIL_MU may be specified in the memory media 110, the controller 120 does not need to repeatedly perform an operation for detecting the failed memory unit.

FIG. 3 is a diagram illustrating an operation in which a memory system determines whether a specific memory unit is a fail memory unit according to embodiments of the present disclosure.

Referring to FIG. 3, a controller 120 of a memory system 100 may count the number of memory cells that have failed in a specific memory unit (S310). For example, the controller 120 may count the number of memory cells that have failed during a read or write operation on a memory unit within a predetermined time period.

The controller 120 determines whether the number of memory cells that have failed in the memory unit is equal to or greater than a threshold (S320).

When the number of failed memory cells in the memory unit is equal to or greater than the threshold (S320-Y), the controller 120 may determine that the corresponding memory unit is a fail memory unit FAIL_MU (S330).

On the other hand, when the number of failed memory cells in the corresponding memory unit is smaller than the threshold (S320-N), the controller 120 may determine that the corresponding memory unit is not a fail memory unit FAIL_MU (S340).

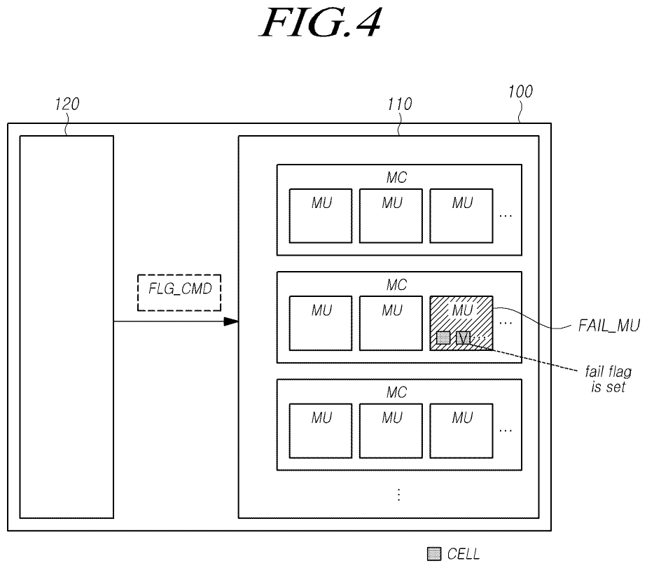

FIG. 4 is a diagram illustrating an operation in which a memory system sets a fail flag in a fail memory unit according to embodiments of the present disclosure.

Referring to FIG. 4, a memory media 110 of a memory system 100 may receive a fail flag set command FLG_CMD from a controller 120, and in response to the fail flag set command FLG_CMD, may set a fail flag for at least one of the memory cells CELL in a fail memory unit FAIL_MU.

The location of a memory cell CELL with a fail flag within the fail memory unit FAIL_MU may be determined in various ways.

For example, the memory cell CELL with the fail flag may be located at a preset address from among the memory cells CELL included in the fail memory unit FAIL_MU.

In another example, the memory cell CELL with the fail flag may be included in a reserved area in which data write-requested by the controller 120 is not stored.

In the above examples, operations in which a memory system 100 detects a fail memory unit FAIL_MU and sets a fail flag for the detected fail memory unit FAIL_MU have been described.

Hereinafter, an operation will be described in which a memory system 100 reads data stored in a fail memory unit FAIL_MU in which the fail flag is set.

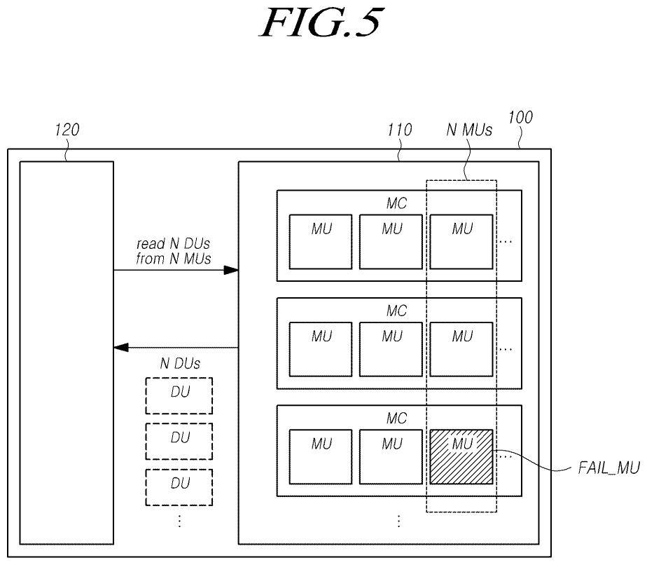

FIG. 5 is a diagram illustrating an operation in which a memory system reads an N number of data units from an N number of memory units according to an embodiment of the present disclosure.

Referring to FIG. 5, a controller 120 of a memory system 100 may read an N (where N is a natural number of 2 or greater) number of data units DU from an N number of memory units MU from among the plurality of memory units MU included in the memory media 110. Each of the N number of memory units MU may store one of the N number of data units DU.

The N number of memory units MU may be included in different memory chips MC. The controller 120 may read the N number of data units DU from the N number of memory units MU in parallel.

In FIG. 5, one of the N number of memory units MU may be a fail memory unit FAIL_MU. That is to say, the controller 120 may read the data units DU stored in an N−1 number of normal memory units MU and the fail memory unit FAIL_MU.

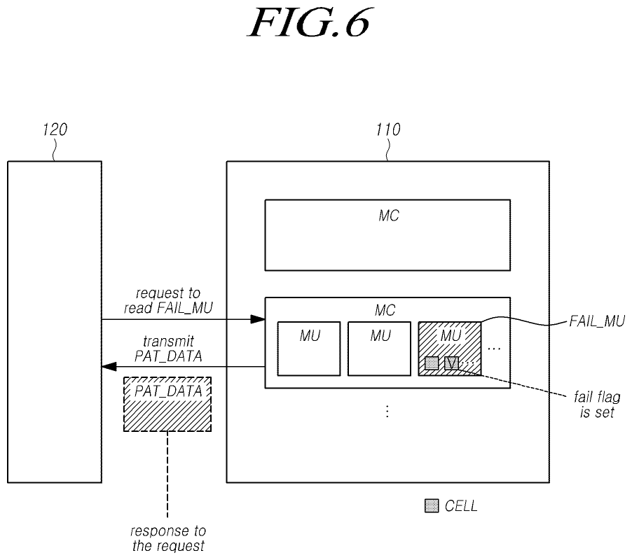

FIG. 6 is a diagram illustrating an operation in which a memory system reads a fail memory unit according to the embodiments of the present disclosure.

Referring to FIG. 6, a controller 120 of a memory system 100 may transmit to a memory media 110 a read request that includes a fail memory unit FAIL_MU. The controller 120 does not know, however, whether the read request targets memory units MU with the fail memory unit FAIL_MU.

The memory media 110, however, may check whether the controller 120 has transmitted a read request for the fail memory unit FAIL_MU using the fail flag set for the fail memory unit FAIL_MU.

In response to the read request for the fail memory unit FAIL_MU, the memory media 110 may transmit a preset pattern data PAT_DATA.

In other words, the memory media 110 transmits to the controller 120 the preset pattern data PAT_DATA instead of transmitting data actually stored in the fail memory unit FAIL_MU, thereby indicating that the memory unit MU subject to the read request from the controller 120 is a fail memory unit FAIL_MU.

The pattern data PAT_DATA may be determined in various ways.

For example, all bits of the pattern data PAT_DATA may be 0.

In another example, all bits of the pattern data PAT_DATA may be 1.

In still another example, the pattern data PAT_DATA may be an ID value preset for the memory media 110.

In embodiments of the present disclosure, when the controller 120 of the memory system 100 reads an N number of data units DU from an N number of memory units MU and one of the N number of memory units MU is a fail memory unit FAIL_MU, one of the N number of data units DU may include the pattern data PAT_DATA.

The pattern data PAT_DATA is data generated by the memory media 110 and is not data, stored in a memory unit MU, that would be responsive to the read request. Therefore, the controller 120 needs to restore a data unit DU including the pattern data PAT_DATA in order to generate data that is actually stored in the failed memory unit in the memory media 110.

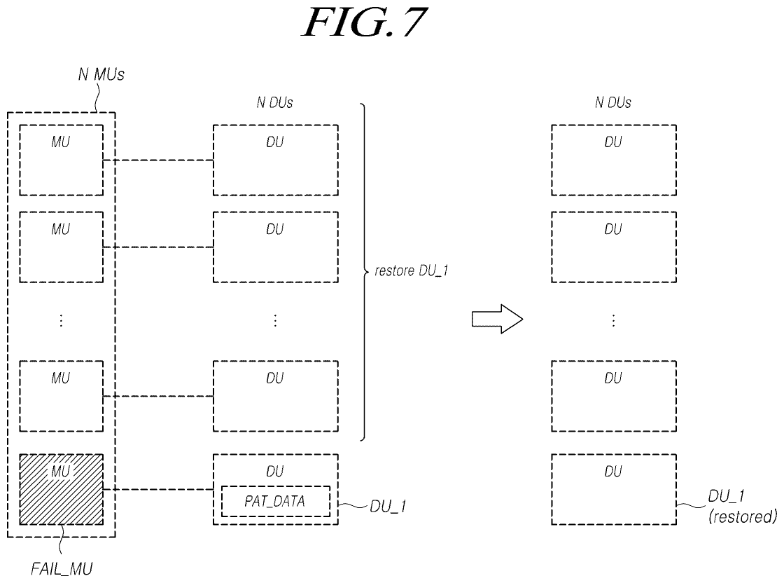

The controller 120 may detect a first data unit DU_1 with the pattern data PAT_DATA from among the N number of data units DU, and may perform a restoration operation on the first data unit DU_1. This will be described in detail below with reference to FIG. 7.

FIG. 7 is a diagram illustrating an operation in which a memory system restores a data unit according to an embodiment of the present disclosure.

Referring to FIG. 7, a controller 120 of a memory system 100 may restore a first data unit DU_1, from among the N number of data units DU, that includes pattern data PAT_DATA using remaining data units except the first data unit DU_1. The N number of data units DU correspond to an N number of memory units MU, respectively, described above with reference to FIG. 5. Among the N number of data units DU, the first data unit DU_1 corresponds to the fail memory unit FAIL_MU.

The controller 120 may check through the pattern data PAT_DATA included in the first data unit DU_1 to confirm that the first data unit DU_1 is a data unit DU in which a fail has occurred from among the N number of data units DU.

As a result, the controller 120 does not need to separately track and manage data units DU in which a fail has occurred. In addition, error correction operations do not need to be executed repeatedly across all of the N number of data units DU to detect a data unit DU with a failure. As a result, the controller 120 may more quickly restore a data unit DU in which a fail has occurred.

The controller 120 may restore the first data unit DU_1 using various algorithms.

For example, the controller 120 may restore the first data unit DU_1 using an erasure coding algorithm.

Erasure coding is a data restoration technique that, when a fail has occurred in a part of data encoded using a coding matrix called an erasure code, restores data through a decoding process using a remaining part of the data where a fail has not occurred.

Erasure coding may use a data area and a parity area set to suit a user environment, so the reliability of data and an overhead caused during a restoration process may vary depending on sizes of the data area and the parity area.

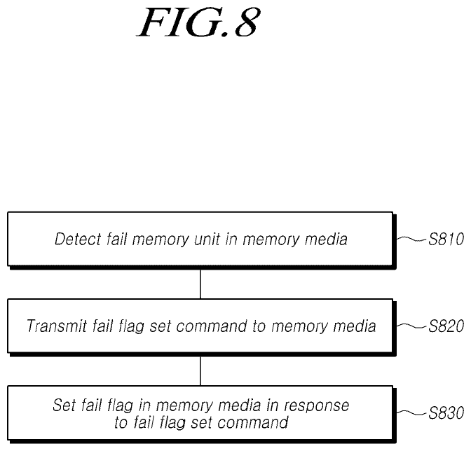

FIG. 8 is a diagram illustrating a method for operating a memory system according to embodiments of the present disclosure.

Referring to FIG. 8, a method for operating a memory system 100 may include step S810 of detecting a fail memory unit FAIL_MU in a memory media 110. The memory media 110 may include a plurality of memory chips MC. Each of the plurality of memory chips MC may include a plurality of memory units MU. Each of the plurality of memory units MU may include a plurality of memory cells CELL.

For example, in step S810, among the plurality of memory units MU included in the memory media 110, a memory unit MU in which the number of failed memory cells is equal to or greater than a threshold may be determined as a fail memory unit FAIL_MU.

The method for operating the memory system 100 may include a step S820 of transmitting to the memory media 110 a fail flag set command FLG_CMD, which instructs setting of a fail flag for the fail memory unit FAIL_MU.

The method for operating the memory system 100 may include a step S830 of setting a fail flag in the memory media 110 in response to the fail flag set command FLG_CMD.

For example, in step S830 a fail flag may be set for at least one among the plurality of memory cells CELL included in the fail memory unit FAIL_MU.

The method for operating the memory system 100 may further include reading an N (where N is a natural number of 2 or greater) number of data units DU from an N number of memory units MU among a plurality of memory units MU included in the memory media 110. One of the N number of memory units MU may be a fail memory unit FAIL_MU.

A data unit read from the fail memory unit FAIL_MU may include a preset pattern data PAT_DATA. For example, all bits of a preset pattern data PAT_DATA may be 0.

The method for operating the memory system 100 may further include a step of restoring a first data unit DU_1, which includes the pattern data PAT_DATA, among the N number of data units DU.

For example, the step of restoring the first data unit DU_1 may restore the first data unit DU_1 using an erasure coding algorithm.

Although exemplary embodiments of the disclosure have been described for illustrative purposes, those skilled in the art will appreciate that various modifications, additions and substitutions are possible, without departing from the scope and spirit of the disclosure. Therefore, the embodiments disclosed above and in the accompanying drawings should be considered in a descriptive sense only and not for limiting the technological scope. The technological scope of the disclosure is not limited by the embodiments and the accompanying drawings. The spirit and scope of the disclosure should be interpreted in connection with the appended claims and encompass all equivalents falling within the scope of the appended claims.

What is claimed is:

1. A memory system comprising:
a memory media including a plurality of memory chips, each of the plurality of memory chips including a plurality of memory units and each of the plurality of memory units including a plurality of memory cells; and
a controller configured to detect a fail memory unit from among the plurality of memory units included in the memory media, and transmit to the memory media a fail flag set command for setting a fail flag for the fail memory unit.

2. The memory system according to claim 1, wherein the controller determines the fail memory unit, from among the plurality of memory units included in the memory media, as a memory unit in which a number of failed memory cells is equal to or greater than a threshold.

3. The memory system according to claim 1, wherein the memory media receives the fail flag set command, and sets the fail flag for at least one of the plurality of memory cells included in the fail memory unit.

4. The memory system according to claim 1, wherein the controller reads an N number of data units from an N number of memory units among the plurality of memory units included in the memory media, one of the N number of memory units is the fail memory unit, and N is a natural number of 2 or greater.

5. The memory system according to claim 4, wherein the memory media transmits, in response to a read request for the fail memory unit, a preset pattern data to the controller.

6. The memory system according to claim 5, wherein all bits of the preset pattern data are 0.

7. The memory system according to claim 5, wherein the controller restores data of the fail memory unit including the preset pattern data using remaining data units, except the fail memory unit, among the N number of data units.

8. The memory system according to claim 7, wherein the controller restores the data of the fail memory unit using an erasure coding algorithm.

9. A method for operating a memory system, comprising:
detecting a fail memory unit in a memory media including a plurality of memory chips, each of the plurality of memory chips including a plurality of memory units and each of the plurality of memory units including a plurality of memory cells;
transmitting to the memory media a fail flag set command for setting a fail flag for the fail memory unit; and
setting the fail flag in the memory media in response to the fail flag set command.

10. The method according to claim 9, wherein the detecting the fail memory unit further comprises determining, as the fail memory unit from among the plurality of memory units included in the memory media, a memory unit in which a number of failed memory cells is equal to or greater than a threshold.

11. The method according to claim 9, wherein the setting the fail flag further comprises setting the fail flag for at least one of the plurality of memory cells included in the fail memory unit.

12. The method according to claim 9, further comprising:
reading an N number of data units from an N number of memory units among the plurality of memory units included in the memory media,
wherein one of the N number of memory units is the fail memory unit, and
wherein N is a natural number of 2 or greater.

13. The method according to claim 12, wherein reading data from the fail memory unit returns a preset pattern data.

14. The method according to claim 13, wherein all bits of the preset pattern data are 0.

15. The method according to claim 14, further comprising:
restoring data from the fail memory unit including the preset pattern data.

16. The method according to claim 15, wherein the restoring data from the fail memory unit restores the data using an erasure coding algorithm.
